(19) United States
(12) Patent Application Publication
(10) Pub. No.: US 2009/0255798 A1
(43) Pub. Date: Oct. 15, 2009

(54) METHOD TO PREVENT PARASITIC PLASMA GENERATION IN GAS FEEDTHRU OF LARGE SIZE PECVD CHAMBER

(76) Inventors: Gaku Furuta, Sunnyvale, CA (US); Young-Jin Choi, Santa Clara, CA (US); Soo Young Choi, Fremont, CA (US); Beom Soo Park, San Jose, CA (US); John M. White, Hayward, CA (US); Suhail Anwar, San Jose, CA (US); Robin L. Tiner, Santa Cruz, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/271,616

(22) Filed: Nov. 14, 2008

Related U.S. Application Data
(60) Provisional application No. 61/044,481, filed on Apr. 12, 2008.

(51) Int. Cl. C23C 16/513

(52) U.S. Cl. 204/157.15; 118/723 I; 118/723 IR

(57) ABSTRACT

The present invention generally includes a plasma enhanced chemical vapor deposition (PECVD) processing chamber having an RF power source coupled to the backing plate at a location separate from the gas source. By feeding the gas into the processing chamber at a location separate from the RF power, parasitic plasma formation in the gas tubes leading to the processing chamber may be reduced. The gas may be fed to the chamber at a plurality of locations. At each location, the gas may be fed to the processing chamber from the gas source by passing through a remote plasma source as well as an RF choke or RF resistor.

### CROSS-REFERENCE TO RELATED APPLICATIONS

This application claims benefit of U.S. provisional patent application Ser. No. 61/044,481 (APPM/013370L), filed Apr. 12, 2008, which is herein incorporated by reference.

### BACKGROUND OF THE INVENTION

1. Field of the Invention

Embodiments of the present invention generally relate to a processing chamber having the power supply coupled to the processing chamber at a location separate from the gas supply.

2. Description of the Related Art

As demand for larger flat panel displays and solar panels continues to increase, so must the size of the substrate and hence, the processing chamber. As the processing chamber size increases, higher RF current is sometimes necessary in order to offset dissipation of the RF current that occurs as the RF current travels away from the RF source. One method for depositing material onto a substrate for flat panel displays or solar panels is plasma enhanced chemical vapor deposition (PECVD). In PECVD, process gases may be introduced into the process chamber through a showerhead and ignited into a plasma by an RF current applied to the showerhead. As substrate sizes increase, the RF current applied to the showerhead may also correspondingly increase. With the increase in RF current, the possibility of premature gas breakdown prior to the gas passing through the showerhead increases as does the possibility of parasitic plasma formation above the showerhead.

Therefore, there is a need in the art for an apparatus that permits the delivery of sufficient RF current while reducing parasitic plasma formation.

### SUMMARY OF THE INVENTION

The present invention generally includes a PECVD processing chamber having an RF power source coupled to the backing plate at a location separate from the gas source. By feeding the gas into the processing chamber at a location separate from the RF power, parasitic plasma formation in the gas tubes leading to the processing chamber may be reduced. The gas may be fed to the chamber at a plurality of locations. At each location, the gas may be fed to the processing chamber from the gas source by passing through a remote plasma source as well as an RF choke or RF resistor.

In one embodiment, plasma processing apparatus is disclosed. The apparatus may comprise a processing chamber having a gas distribution plate and a backing plate. The apparatus may also comprise one or more power sources coupled to the backing plate and one or more gas sources coupled to the backing plate at a location separate from where the one or more power sources are coupled to the backing plate.

In another embodiment, a plasma processing apparatus is disclosed. The apparatus may include a processing chamber having a gas distribution plate and a backing plate and a power source coupled to the backing plate at a first location corresponding to the center of the backing plate. The apparatus may also include a gas source coupled to the backing plate at a plurality of second locations. Each second location may be separate from the first location.

In another embodiment, a method is disclosed. The method includes flowing electrical current to a backing plate at one or more first locations and flowing gas through the backing plate at a second location different from the first location.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic representation of a power source 102 and a gas source 104 coupled to a processing chamber 100 according to one embodiment of the invention.

FIG. 2A is a schematic cross-sectional view of a processing chamber 200 according to one embodiment of the invention.

FIG. 2B is a schematic cross-sectional view of the processing chamber 200 of FIG. 2A showing the RF current path.

FIG. 3 is a schematic isometric view of a backing plate 302 of a processing chamber 300 according to one embodiment of the invention.

FIG. 4 is a schematic illustration of a coupling between a remote plasma source and the processing chamber according to one embodiment of the invention.

FIG. 5 is a schematic isometric view of a backing plate 502 of a processing chamber 500 according to one embodiment.

FIG. 6 is a schematic top view of a substrate support showing locations of corresponding gas introduction passages according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally includes a PECVD processing chamber having an RF power source coupled to the backing plate at a location separate from the gas source. By feeding the gas into the processing chamber at a location separate from the RF power, parasitic plasma formation in the gas tubes leading to the processing chamber may be reduced. The gas may be fed to the chamber at a plurality of locations. At each location, the gas may be fed to the processing chamber from the gas source by passing through a remote plasma source as well as an RF choke or RF resistor.

The invention is illustratively described below in reference to a chemical vapor deposition system, processing large area substrates, such as a PECVD system, available from AKT American, Inc., a division of Applied Materials, Inc., Santa Clara, Calif. However, it should be understood that the apparatus and method may have utility in other system configurations, including those systems configured to process round substrates.

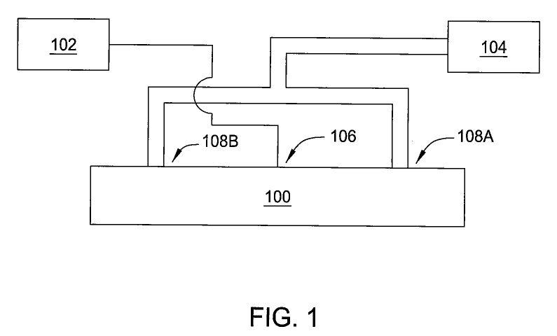

FIG. 1 is a schematic representation of a power source 102 and a gas source 104 coupled to a processing chamber 100 according to one embodiment of the invention. As shown in FIG. 1, the power source 102 is coupled to the processing chamber 100 at a location 106 that is different from the locations 108A, 108B where the gas source 104 is coupled to the processing chamber 100.

It is to be understood that while two locations 108A, 108B have been shown for coupling the gas source 104 to the processing chamber 100, the number of locations 108A, 108B is not to be limited to two. A single location 108A, 108B may be utilized. Alternatively, more than two locations 108A, 108B may be used. When a plurality of locations 108A, 108B are used to couple the gas source 104 to the processing chamber 100, the gas may flow to the processing chamber 100 to the plurality of locations 108A, 108B from a common gas source 104. In one embodiment, each location 108A, 108B where gas flows to the processing chamber 100 may have its own dedicated gas source 104.

It is also to be understood that while a single location 106 is shown for coupling the power source 102 to the processing chamber 100, the power source 102 may be coupled to the processing chamber 100 at a plurality of locations 106. In one embodiment, the power source 102 may comprise an RF power source. Additionally, while the power source 102 is shown to be coupled to the processing chamber 100 at a location 106 that corresponds to the substantial center of the processing chamber 100, the power source 102 may be coupled to the processing chamber 100 at a location 106 that does not correspond to the substantial center of the processing chamber 100.

While the gas source 104 is shown to be coupled to the processing chamber 100 at locations 108A, 108B that are disposed substantially away form the center of the processing chamber 108A, 108B, the location 108A, 108B are not so limited. The locations 108A, 108B may be located closer to the center of the processing chamber 100 than the location 106 where the power source 102 is coupled to the processing chamber 100.

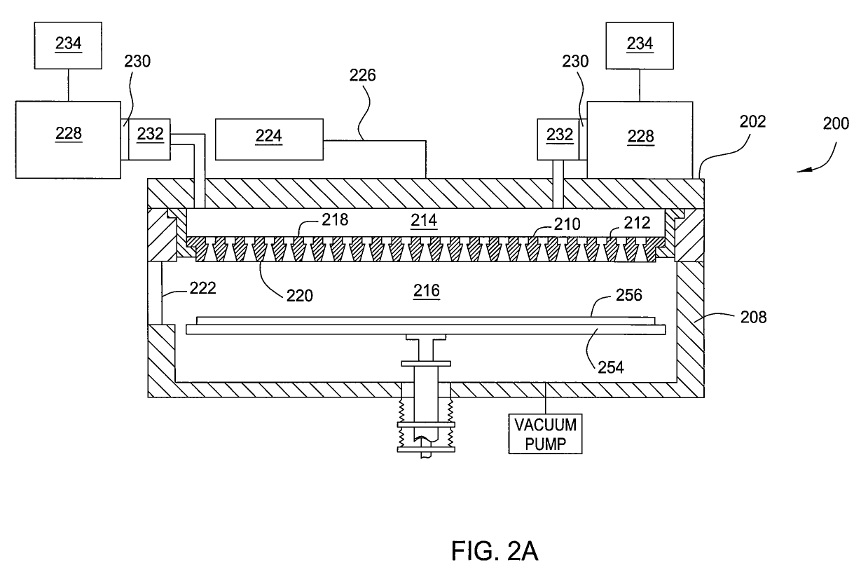

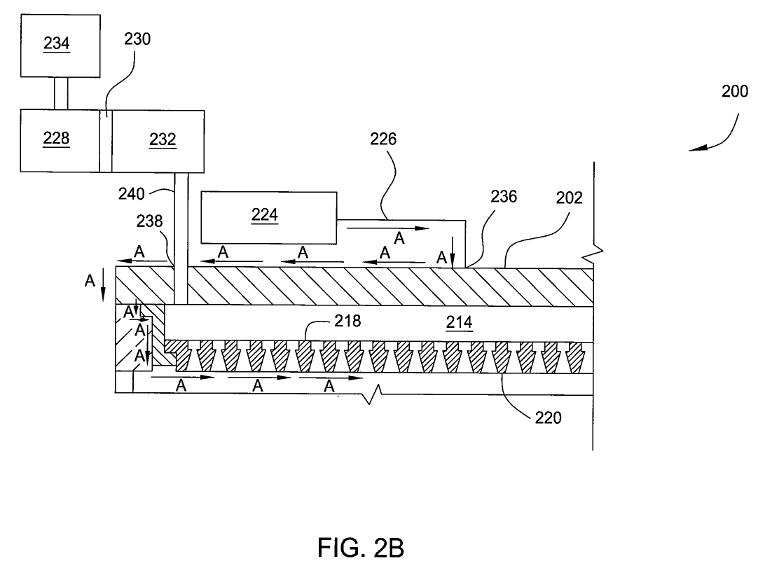

FIG. 2A is a schematic cross-sectional view of a processing chamber 200 according to one embodiment of the invention. The processing chamber 200 is a PECVD chamber. The processing chamber 200 has a chamber body 208. Within the chamber body, a susceptor 204 may be disposed to sit opposite a gas distribution showerhead 210. A substrate 206 may be disposed on the susceptor 204. The substrate 206 may enter the processing chamber 200 through a slit valve opening 222. The substrate 206 may be raised and lowered by the susceptor 204 for processing, removal and/or insertion of the substrate 206.

The showerhead 210 may have a plurality of gas passages 212 passing through the showerhead 210 form an upstream side 218 to a downstream side 220. The downstream side 220 of the showerhead 210 is the side of the showerhead that faces the substrate 206 during processing.

The showerhead 210 is disposed in the processing chamber 200 across a processing space 216 from the substrate 206. Behind the showerhead 210, a plenum 214 is present. The plenum 214 is between the showerhead 210 and the backing plate 202.

Power to the showerhead 210 may be provided by a power source 224 that is coupled to the backing plate via a feed line 226. In one embodiment, the power source 224 may comprise an RF power source. In the embodiment shown, the feed line 226 couples to the backing plate 202 at a location corresponding to the substantial center of the backing plate 202. It is to be understood that the power source 224 may couple to the backing plate 202 at other locations as well.

Processing gas may be delivered from a gas source 234 to the processing chamber 200 through the backing plate 202. The gas from the gas source 234 may travel through a remote plasma source 228 prior to reaching the processing chamber 200. In one embodiment, the processing gas passes through the remote plasma source 228 for deposition and thus, does not ignite into a plasma within the remote plasma source 228. In another embodiment, the gas from the gas source 234 may be ignited into a plasma in the remote plasma source 228 and then sent to the processing chamber 200. The plasma from the remote plasma source 228 may clean the processing chamber 200 and the exposed components therein. Additionally, the plasma may clean the cooling block 230 and the choke or resistor 232 through which the gas passes after the remote plasma source 228.

When a plasma is ignited in the remote plasma source 228, the remote plasma source 228 may be become very hot. Thus, a cooling block 230 may be disposed between the choke or resistor 232 and the remote plasma source 228 to ensure that the choke or resistor 232 does not crack due to the high temperatures of the remote plasma source 228.

It is to be understood that while two separate gas sources 234 have been shown the remote plasma sources 228 may share a common gas source 234. Additionally, while a remote plasma source 228 is shown coupled between each gas source 234 and the backing plate, the processing chamber 200 may have more or less remote plasma sources 228 coupled to it.

FIG. 2B is a schematic cross-sectional view of the processing chamber 200 of FIG. 2A showing the RF current path. RF current has a “skin effect” whereby the RF current travels on the outside surface of an electrically conductive object and only penetrates into the object to a certain depth. Thus, for a sufficiently thick object, the inside of the object may have a zero RF current detectable while the outside surface may have RF current flowing thereon and be considered RF “hot”.

Arrow “A” shows the path that the RF current takes from the power source 224 to the showerhead 210. The RF current travels from the power source 224 along the feed line 226. At location 236, the RF current encounters the backing plate 202 and flows along the back surface of the backing plate 202 and down to the upstream surface 220 of the showerhead 210.

The gas enters the processing chamber 200 through the backing plate 202 at a location 238. Arrow “B” shows the distance between the location 238 where the gas enters the processing chamber 200 and the location 236 where the RF current encounters the backing plate 202. As RF current travels, it may tend to dissipate. In other words, the RF current leaving the power source 224 may have a higher power level as compared to the power level further down the line. In the embodiment shown in FIG. 2B, the RF current at location 236 may have a higher power level as compared to the RF current flowing along the backing plate 202 as it passes location 238 where the gas enters the processing chamber 200. Due to the lower amount of power at location 238 as compared to location 236, the possibility of the gas igniting within the tube 240 containing the gas entering the processing chamber 200 may be reduced. Because of the decreased likelihood of the processing gas igniting in the tube 240, parasitic plasma formation in the tube 238, choke or resistor 232, cooling block 230, remote plasma source 228, and plenum 214 behind the showerhead 210 may be reduced. In one embodiment, the tube 240 may comprise ceramic material.

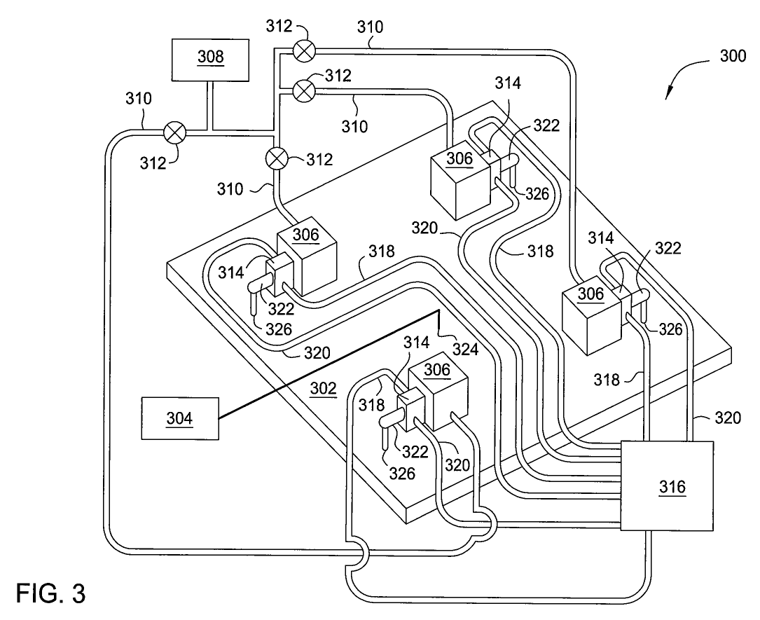

FIG. 3 is a schematic isometric view of a backing plate 302 of a processing chamber 300 according to one embodiment of the invention. RF power may be supplied to the chamber 300 by coupling an RF power source 304 to the backing plate 302 at a location 324. While the location 324 has been shown to correspond to the substantial center of the backing plate 302, it is to be understood that the location 324 may be located at various other points on the backing plate 324. Additionally, more than one location 324 may be simultaneously utilized.

A common gas source 308 may supply the gas to the processing chamber 300. It is to be understood that while a single gas source 308 is shown, multiple gas sources 308 may be utilized. The gas from the gas source 308 may be supplied to the remote plasma sources 306 through gas tubes 310. It is to be understood that while four remote plasma sources 306 are shown, more or less remote plasma sources 306 may be utilized. Additionally, while the remote plasma sources 306 are shown disposed above the backing plate 302, the remote plasma sources 306 may be disposed adjacent the backing plate 302.

The gas from the gas source 308 passes through the gas tubes 310 to the remote plasma sources 306. If the processing chamber 300 is operating in a cleaning mode, the gas in the remote plasma source 306 may be ignited into a plasma and fed to through the cooling block 314 and choke or resistor 322 to the processing chamber 300. However, if the processing chamber is operating in a deposition mode, the gas will pass through the remote plasma source 306 without igniting into a plasma. Without igniting a plasma, the cleaning gas enters the processing chamber in a non-plasma state and may contribute to cleaning inefficiencies.

If one or the remote plasma sources 306 fails or does not run efficiently, the remote plasma source 306 may be shut off. If the other remote plasma sources 306 operate as desired, cleaning gas flowing through the non-functioning remote plasma source 306 into the processing chamber 300 does not ignite prior to entering the processing chamber 300. In such a scenario, the processing chamber 300 cleaning may not proceed as efficiently.

TABLE I

| NF₃ | | RPS | |
|---|---|---|---|
| flow | RPS | units | |
| rate | units | not | Cleaning |
| (slm) | working | working | time (s) |
| 24 | all | none | 24.2 |
| 36 | all | none | 29.5 |
| 48 | all | none | 38 |
| 48 | 3 | 1 | 87.3 |
| 48 | 3 | 1 | 92.2 |
| 48 | 2 | 2 | 248.3 |
| 48 | 2 | 2 | 84.4 |
| 48 | 2 | 2 | 118.9 |

Table I shows the effects of cleaning the chamber whenever one or more remote plasma sources does not work. The chamber is cleaned after SiN deposition. In the data shown in Table I, when the RPS is not working, gas continues to flow through the RPS unit to the chamber. As can be seen form Table I, when one or more RPS units stops functions, but cleaning gas continues to flow therethrough, the cleaning time increases. However, when the RPS unit fails, but the gas is shut off to the failed RPS unit, cleaning time may not increase.

TABLE II

| NF₃ | | 3 of 4 | | | 3 of 4 | |
|---|---|---|---|---|---|---|
| flow | 1 RPS | RPS | 4 RPS | 1 RPS | RPS | 4 RPS |
| rate | unit | units | units | unit | units | units |
| (slm) | (SiN) | (SiN) | (SiN) | (a-Si) | (a-Si) | (a-Si) |
| 20 | 50.4 | 38.9 | 36.4 | 24.8 | 27.9 | 23.2 |
| 24 | 45.4 | 34.9 | 32.3 | 21.4 | | |
| 27 | 43.0 | 32.6 | 30.6 | 19.9 | 22.6 | 19.0 |
| 36 | | 29.7 | 26.1 | | | |
| 48 | | 22.8 | 22.5 | | 16.8 | 11.4 |

As shown in Table II, by shutting off the gas to a failed RPS unit, the cleaning rate may be substantially maintained. Therefore, it may be beneficial to close a valve 312 in the gas line 310 to prevent cleaning gas from flowing through a non-working remote plasma source 306 and entering the processing chamber 300 without being ignited into a plasma in the remote plasma source 306. Thus, by closing a valve 312, gas flow may be diverted away from a non-working remote plasma source 306. Therefore, the processing chamber 300 may be cleaned utilizing fewer remote plasma sources 306 then are coupled to the backing plate 302. In one embodiment, the valve 312 may be located after the remote plasma source 306.

After passing through a remote plasma source 306, the gas may pass through a cooling block 314. The cooling block 314 may be coupled to a cooling source 316 that flows a cooling fluid to the cooling block 314 through cooling tubes 318. Cooling fluid may flow out of the cooling block 314 and back to the cooling fluid source 316 through a cooling tube 320. The cooling block 314 provides an interface between the remote plasma source 306 and the choke or resistor 322 such that cracking of the choke or resistor 322 is reduced.

After passing through the cooling block 314, the gas passes through a choke or resistor 322. In one embodiment, the choke or resistor 322 may comprise an electrically insulating material such as ceramic. The electrically insulating material may prevent RF power from traveling along the path that the gas flows. The gas may enter the processing chamber 300 through the backing plate 302 at location 326. It is to be understood that while four locations 326 are shown, more or less locations 326 may be utilized for introducing the gas to the processing chamber 300. Additionally, the locations 326 need not be situated near the corners of the backing plate 302. For example, the locations 326 may be situated closer to the center of the backing plate 302.

Additionally, the location 324 where the RF power couples to the backing plate 302 and the locations 326 where the gas enters the processing chamber 300 are not limited to the locations shown. The location 324 may be situated closer to the edge of the backing plate 302 while one or more gas feed locations 326 may be situated in an area corresponding to the center of the backing plate 302.

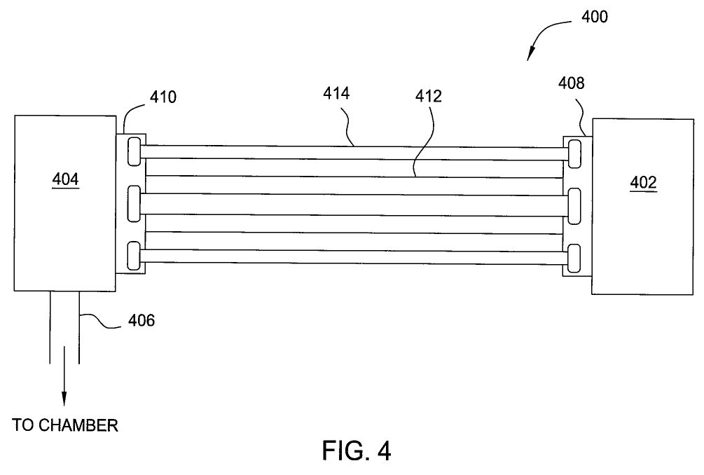

FIG. 4 is a schematic illustration of a coupling between a remote plasma source and the processing chamber according to one embodiment of the invention. A choke or resistor 400 may be coupled between the cooling block 402 and a connection block 404. A resistor 400 is shown in FIG. 4, but it is to be understood that a choke may be used instead. In order to make a choke, a metal coil, such as a copper coil, it wrapped around the outside of the resistor 400. The connection block 404 may be coupled to a tube 406 that permits the gas flowing through the choke or resistor 400 flow into the backing plate. In one embodiment, the tube 406 may comprise ceramic. Additionally, in one embodiment, the connection block 404 may comprise ceramic. In another embodiment, the connection block 404 may comprise stainless steel. In another embodiment, the connection block 404 may comprise aluminum. When the connection block 404 comprises a metal, an electrically insulating material may be used for a tube that connects the tube 412 of the choke or resistor 400 and the tube 406 to the chamber. The cooling block 402 may comprise metal.

The choke or resistor 400 may comprise an inner tube 412 through which gas flows through to reach the chamber. In one embodiment, the inner tube 412 may comprise an electrically insulating material. In another embodiment, the inner tube 412 may comprise ceramic. The inner tube 412 may be present within a casing 414. In one embodiment, the casing 414 may comprise an electrically insulating material. In another embodiment, the casing 414 may comprise ceramic. The electrically insulating material permits the processing gas to flow within the tube without exposing the gas to RF current.

The casing 414 and tube 412 may connect to the connection block 404 at one end 410 and to the cooling block 402 at another end 408. While not shown, electrically conductive material may be wound around the casing 414 in some embodiments. The electrically conductive material may be utilized to provide an additional RF current path to ground if necessary.

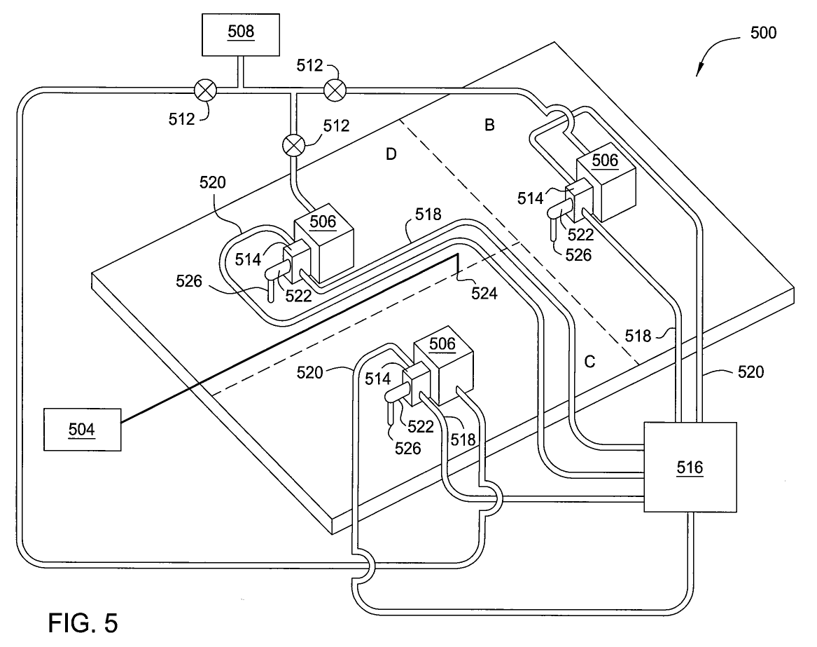

FIG. 5 is a schematic isometric view of a backing plate 502 of a processing chamber 500 according to one embodiment showing three locations for gas feed. The three locations are substantially centered over a substrate that is hypothetically divided into three substantially equal areas. The dashed lines divide the three substantially equal areas. RF power may be supplied to the chamber 500 by coupling an RF power source 504 to the backing plate 502 at a location 524. While the location 524 has been shown to correspond to the substantial center of the backing plate 502, it is to be understood that the location 524 may be located at various other points on the backing plate 524. Additionally, more than one location 524 may be simultaneously utilized.

A common gas source 508 may supply the gas to the processing chamber 500. It is to be understood that while a single gas source 508 is shown, multiple gas sources 508 may be utilized. The gas from the gas source 508 may be supplied to the remote plasma sources 506 through gas tubes 510. While the remote plasma sources 506 are shown disposed above the backing plate 502, the remote plasma sources 506 may be disposed adjacent the backing plate 502.

The gas from the gas source 508 passes through the gas tubes 510 to the remote plasma sources 506. If the processing chamber 500 is operating in a cleaning mode, the gas in the remote plasma source 506 may be ignited into a plasma and the radicals then fed to through the cooling block 514 and choke or resistor 522 to the processing chamber 500. However, if the processing chamber is operating in a deposition mode, the gas will pass through the remote plasma source 506 without igniting into a plasma. Without igniting a plasma, the cleaning gas enters the processing chamber in a non-plasma state and may contribute to cleaning inefficiencies.

It may be beneficial to close a valve 512 in the gas line 510 to prevent cleaning gas from flowing through a non-working remote plasma source 506 and entering the processing chamber 500 without being ignited into a plasma in the remote plasma source 506. Thus, by closing a valve 512, gas flow may be diverted away from a non-working remote plasma source 506. Therefore, the processing chamber 500 may be cleaned utilizing fewer remote plasma sources 506 then are coupled to the backing plate 502. In one embodiment, the valve 512 may be located after the remote plasma source 506.

After passing through a remote plasma source 506, the gas may pass through a cooling block 514. The cooling block 514 may be coupled to a cooling source 516 that flows a cooling fluid to the cooling block 514 through cooling tubes 518. Cooling fluid may flow out of the cooling block 514 and back to the cooling fluid source 516 through a cooling tube 520. The cooling block 514 provides an interface between the remote plasma source 506 and the choke or resistor 522 such that cracking of the choke or resistor 522 is reduced.

After passing through the cooling block 514, the gas passes through a choke or resistor 522. In one embodiment, the choke or resistor 522 may comprise an electrically insulating material such as ceramic. The electrically insulating material may prevent RF power from traveling along the path that the gas flows. The gas may enter the processing chamber 500 through the backing plate 502 at location 526.

Additionally, the location 524 where the RF power couples to the backing plate 502 and the locations 526 where the gas enters the processing chamber 500 are not limited to the locations shown. The location 524 may be situated closer to the edge of the backing plate 502 while one or more gas feed locations 526 may be situated in an area corresponding to the center of the backing plate 502.

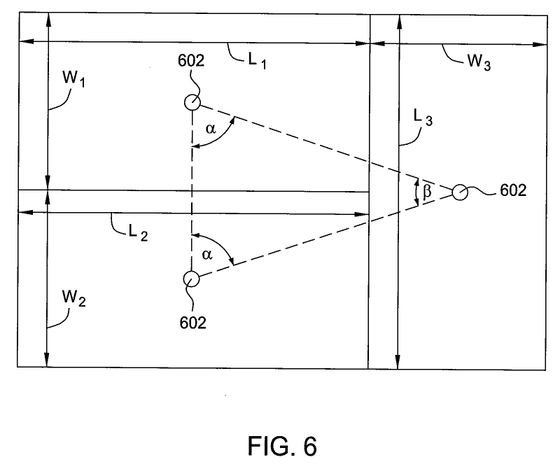

FIG. 6 is a schematic view of a susceptor showing locations of corresponding gas introduction passages. As shown, the susceptor has been divided into three substantially equal areas where the lengths (L1-L3) and the widths (W1-W3) are substantially identical. The center 602 of each area corresponds to the locations above which the gas introductions passages are made through the backing plate. The center 602, and hence, the gas introduction passages, are arranged such that a hypothetical triangle (shown by the dashed lines) has two substantially equals angles (α) and one other angle (β) that may or may not be equal to the other angles (α). Whether angle (β) equals angles (α) will depend upon the layout of the susceptor.

While described as a susceptor, the arrangement could equally apply to the substrate such that the gas passages are centered over three substantially equal areas of a substrate disposed on the susceptor. In another embodiment, the arrangement could equally apply to the backing plate itself such that the gas passages are centered through three substantially equal areas of the backing plate. Additionally, the arrangement could equally apply to a showerhead or electrode such that the gas passages are centered over three substantially equal areas of the showerhead or electrode.

By separating the point where the RF current couples of the backing plate from the location where the processing gas couples to the backing plate, parasitic plasma formation within the gas feed to the processing chamber may be reduced.

While the foregoing is directed to embodiments of the present invention, other and further embodiments of the invention may be devised without departing from the basic scope thereof, and the scope thereof is determined by the claims that follow.

1. A plasma processing apparatus, comprising:
a processing chamber having a gas distribution plate and a backing plate;
one or more power sources coupled to the backing plate; and
one or more gas sources coupled to the backing plate at a location separate from where the one or more power sources are coupled to the backing plate.

2. The apparatus of claim 1, wherein the apparatus is a plasma enhanced chemical vapor deposition apparatus.

3. The apparatus of claim 1, wherein the one or more gas sources are coupled to the backing plate at a plurality of locations.

4. The apparatus of claim 3, wherein the plurality of locations comprise three locations, and where each of the three locations is separate from where the one or more power sources are coupled to the backing plate.

5. The apparatus of claim 4, further comprising a generally rectangular shaped substrate support within the processing chamber, wherein the substrate support is hypothetically divided into there substantially equal portions and the three locations are each substantially centered over a corresponding portion of the substrate support.

6. The apparatus of claim 4, wherein the three locations are arranged such that each location represents a corner of a triangle having two substantially equal angles.

7. The apparatus of claim 1, wherein at least one of the one or more gas sources is coupled to a remote plasma source.

8. The apparatus of claim 7, wherein the at least one or more gas sources are coupled to a plurality of remote plasma sources.

9. The apparatus of claim 1, wherein the backing plate has a substantially rectangular shape and wherein the one or more gas sources are coupled to the backing plate at a plurality of locations that are each separate from the location where the one or more power sources are coupled to the backing plate.

10. A plasma processing apparatus, comprising:
a processing chamber having a gas distribution plate and a backing plate;
a power source coupled to the backing plate at a first location corresponding to the center of the backing plate;
a gas source coupled to the backing plate at a plurality of second locations, each second location is separate from the first location.

11. The apparatus of claim 10, wherein the plurality of second locations comprises three locations.

12. The apparatus of claim 11, further comprising a generally rectangular substrate support within the processing chamber, wherein the substrate support is hypothetically divided into three substantially equal portions, and wherein the three locations are each substantially centered over a corresponding portion of the substrate support.

13. The apparatus of claim 11, wherein the three locations are arranged such that each location represents a corner of a triangle having two substantially equal angles.

14. The apparatus of claim 10, further comprising:
a plurality of remote plasma sources coupled to the gas source, each remote plasma source coupled to the backing plate at the second locations.

15. The apparatus of claim 14, further comprising:
a cooling block coupled between each remote plasma source and the backing plate; and
a gas tube coupled between each cooling block and the backing plate.

16. A method, comprising:
flowing electrical current to a backing plate at one or more first locations; and
flowing gas through the backing plate at a second location different from the first location.

17. The method of claim 16, further comprising igniting a plasma remote from the processing chamber and introducing radicals from the plasma to the chamber through the one or more second locations.

18. The method of claim 16, further comprising:
detecting a non-functioning or inefficiently functioning remote plasma source; and
preventing cleaning gas from flowing through the non-functioning or inefficiently functioning remote plasma source while continuing to supply cleaning gas to one or more other remote plasma sources.

19. The method of claim 16, wherein the second location comprises three locations, each separate from the first location, wherein the three locations are arranged such that each location represents a corner of a triangle having two substantially equal angles.

20. The method of claim 16, wherein the second locations comprises three locations, wherein the backing plate is hypothetically divided into three substantially equal portions, the three locations are each substantially centered through a corresponding portion of the backing plate.
